(19) United States
(12) Patent Application Publication
(10) Pub. No.: US 2023/0030627 A1
(43) Pub. Date: Feb. 2, 2023

(54) SENSOR PACKAGE WITH EMBEDDED INTEGRATED CIRCUIT

(71) Applicant: STMICROELECTRONICS PTE LTD, Singapore (SG)

(72) Inventor: Jing-En LUAN, Singapore (SG)

(73) Assignee: STMICROELECTRONICS PTE LTD, Singapore (SG)

(21) Appl. No.: 17/812,679

(22) Filed: Jul. 14, 2022

Related U.S. Application Data
(60) Provisional application No. 63/226,666, filed on Jul. 28, 2021.

(51) Int. Cl. B81B 7/00; B81C 1/00; H01S 5/02255; H01S 5/02345; H01S 5/0236

(52) U.S. Cl. CPC B81B 7/0061; B81C 1/00309; H01S 5/02255; H01S 5/02345; H01S 5/0236; B81B 2201/0257; B81B 2207/012; B81C 2201/0143; B81C 2203/0792; H04R 19/04

(57) ABSTRACT

Provided is a sensor package with an integrated circuit embedded in a substrate and a sensor die on the substrate. The substrate includes a molding compound that has additives configured to respond to a laser. The integrated circuit is embedded in the molding compound. An opening is through the substrate and is aligned with the sensor die. A lid covers the sensor die and the substrate, forming a cavity. At least one trace is formed on a first surface of the substrate, on an internal sidewall of the opening and on a second surface of the substrate with a laser direct structuring process.

### BACKGROUND

### Technical Field

The present disclosure relates to a sensor package with an embedded integrated circuit having at least one trace formed from a laser direct structuring method.

### Description of the Related Art

Micro-electromechanical system (MEMS) and other sensors are sometimes packaged adjacent to an application specific-integrated circuit (ASIC) on a printed circuit board (PCB).

A MEMS microphone may have a pressure sensitive diaphragm (membrane) that is etched into a silicon wafer by means of a particular MEMS processing and aligned with an opening through the PCB to receive sound. A housing or lid covers the microphone and the ASIC.

MEMS microphones are widely used in consumer products, particularly in mobile applications. Due to current design and manufacturing capabilities, traditional MEMS packaging designs have a large form factor x, y, and z directions. With technological designs in products becoming increasingly smaller in size, the large form packaging size has become challenging and will become an issue in future miniaturization requirements. Furthermore, a low level of integration creates a low yield manufacturing issue.

### BRIEF SUMMARY

The present disclosure is directed to a package that includes a substrate having a first surface opposite to a second surface. A first die is in the substrate and includes a first contact. There is an opening through the substrate. There is a second contact on the second surface of the substrate. A first trace is electrically coupled to the first contact and extends from the first surface through the opening to the second contact on the second surface of the substrate. The first die may be an application specific integrated circuit that is embedded in a laser direct structure molding compound, such as one that includes additives that react to a laser.

The package may include a second trace that extends from the first surface through the opening to the second surface of the substrate. In addition, the package may include a second die on the first surface of the substrate in fluid communication with the opening. In one embodiment, the second die is a microelectromechanical system, such as a microphone. Alternatively, the second die may be an edge emitting laser that is configured to transmit a light signal from a prism into the opening.

A lid attached to the substrate with the embedded first die encloses the second die and creates a cavity. An overall height of the package from the second surface of the substrate to an exterior surface of the lid is smaller than current designs. This thinner package can be integrated into smaller electronic devices as manufacturers continue to reduce the size of their products, like tablet computers, cellular or mobile phones, and laptops. This also provides for more efficient techniques of a producing or manufacturing these packages.

### BRIEF DESCRIPTION OF THE SEVERAL VIEWS OF THE DRAWINGS

FIG. 1 is a cross-sectional view of a package including an embedded die in a substrate according to an embodiment of the present disclosure.

FIG. 2 is a cross-sectional view of a package including an embedded die in a substrate according to an alternative embodiment of the present disclosure.

FIG. 3 is a cross-sectional view of a package including an embedded die in a substrate and with a prism lid having in alternative embodiment.

FIGS. 4-8 are cross-sectional views of a method of manufacturing the package including the embedded die in the substrate of FIG. 1.

FIG. 9 is a bottom view of a package including an embedded die in a substrate according to an embodiment of the present disclosure.

FIGS. 10-13 are cross-sectional and bottom views of a package and a method of manufacturing the package including an embedded die in a substrate, according to an alternative embodiment of the present disclosure.

FIG. 14 is a bottom view of a package including an embedded die in a substrate according to an alternative embodiments of the present disclosure.

### DETAILED DESCRIPTION

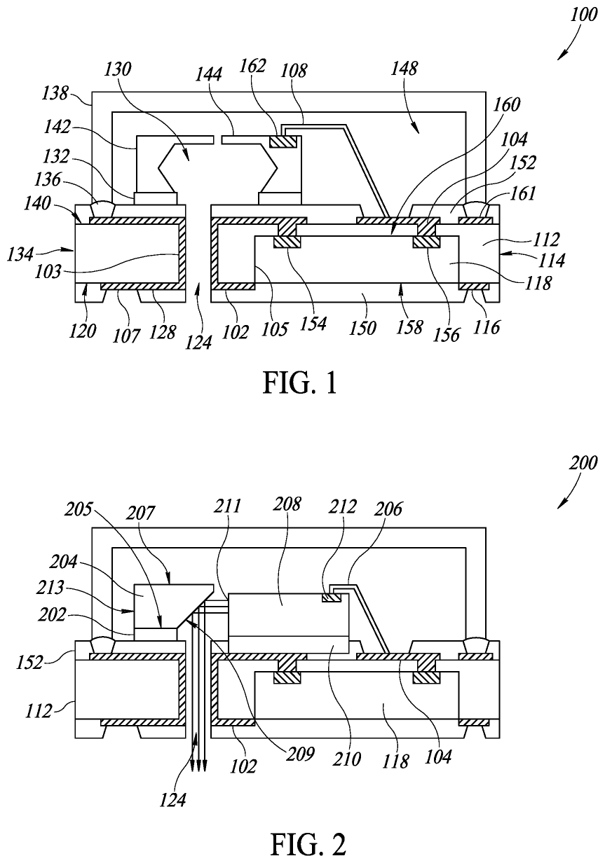

FIG. 1 is directed to a package 100 that includes a first die 118 embedded in a substrate 112, which may be made with a molding compound. The first die 118 in the substrate 112 is positioned between a first surface 140 and a second surface 120. A second die 142, which may be a micro-electromechanical system or a MEMS sensor die is positioned on the substrate 112 using a die attach or adhesive material 132 between the MEMS sensor die 142 and the first surface 140. A lid 138 is attached to the first surface 140 and serves as a housing around the MEMS sensor die 142, extending between a first edge 134 of the substrate 112 to a second edge 114 of the substrate 112. Ends of the lid being spaced inwardly from the first and second edge by a distance.

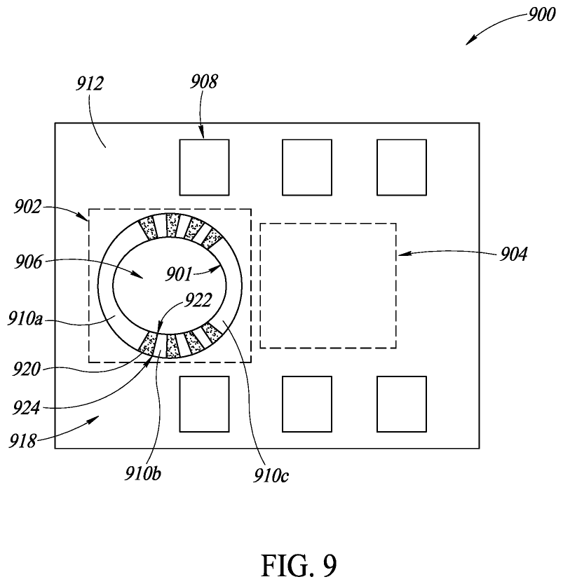

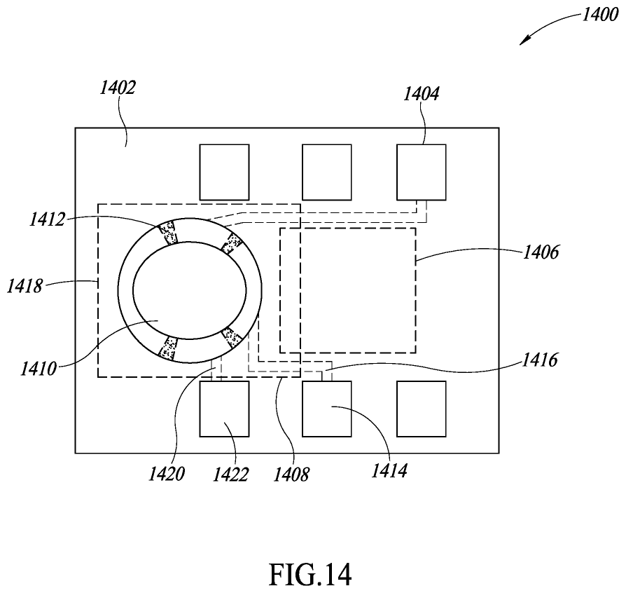

The first die 118 embedded in the substrate 112 has a first surface 158 and a second surface 160. A first opening 124 is adjacent to the first die 118 and is aligned with the second die 142. A first conductive layer 102 is on the first surface 140, on a sidewall 103 of the first opening 124. A second conductive layer 128 is also on the substrate 112 and in the first opening 124. The first opening 124 extends from a first insulating layer 152 to a second insulating layer 150, through the substrate 112 and aligned with the sensing die 142. The first and second conductive layers may be electrically isolated, such as embodiments described in FIGS. 9 and 14 below.

The second surface 120 of the substrate is coplanar with the first surface 158 of the first die 118. The second surface 160 of the first die 118 is coplanar with a first contact pad 154 and a second contact pad 156 in the first die 118. The first contact pad 154 is coupled to the first conductive layer 102 that traces along the edge of the substrate 112 and lines the sidewall of the first opening 124. The first conductive layer 102 extends from an edge 105 of the first die 118 to the sidewall of the first opening 124. This is a first dimension along the second surface 120 of the substrate 112. The first conductive layer 102 extends from the opening 124 to a location between the first and second contact 154, 156 on the first die 118. The first conductive layer 102 is coupled to the first contact pad 154 through a via through the molding compound of the substrate 112. This is a second dimension on the first surface of the substrate. The second dimension is greater than the first dimension.

A second conductive layer 128 traces from the second surface 120 on the substrate 112 along the sidewall of the first opening 124 to the first surface 140 of the substrate 112. An opening through the second insulating layer 150 exposes the second conductive layer 128 as a contact pad 107. The first insulating layer 152 includes an opening that provides access to the second conductive layer 128. The lid 138 includes an attach 136 that extends from the lid 138, through the first insulating layer 152 and is coupled to the second conductive layer 128. The lid is also coupled to a contact pad 161 through a conductive adhesive or attach 136.

The first insulating layer 152 extends from the first edge 134 to the first opening 124, and is positioned or formed on the second conductive layer 128. The second insulating layer 150 is extending from the first edge 134 to the first opening 124 such that in one embodiment, interior surfaces of the first and second insulating layers are coplanar with an interior surface of the second conductive layer 128.

On the second side of the substrate 112, the first insulating layer 152 extends from the first opening 124 to a second edge 114. The first insulating layer 152 includes an opening that provides an access point to a third conductive layer 104 from the sensing die 142. The third conductive layer 104 is a trace formed on the substrate 112 and is coupled to the contact pad 156. The third conductive layer 104 is coupled by a wire 108 that extends from the third conductive layer 104 to a contact pad 162 on the sensing die 142.

On the second side of the substrate 112, the second insulating layer 150 extends from the opening 124 to the second edge 114, with an opening that provides access to a contact pad 116. The second contact pad 156 in the first die 118 is coupled to a third conductive layer 104 on the substrate 112.

The first die 118 may be an application specific integrated circuit or other integrated circuit configured to control and communicate with the second die, such as sending drive signals and receiving data. In standard packages, the first and second die are typically coupled to a single printed circuit board instead of being integrated into a single package.

The first and second insulating layers 150, 152 may be solder resist or other known dielectric liner materials used in packaging techniques. In the present embodiment, the sensing die 142 is positioned on the substrate 112 and may contain a vibrating membrane 144, which may be a MEMS microphone. The sensor die 142 is coupled to the first insulating 152 with the sensor attach 132, such that a chamber 130 is in fluid communication with the opening 124 and the opening through the membrane or cantilever 144. The lid 138 also forms a chamber 148 in which the MEMS sensor die 142 is positioned.

The sensing die 142 is aligned with the opening 124 on the first side of the substrate, with the vibrating membrane 144 transverse to the opening 124. The MEMS microphone functions as a transducer that converts sound pressure into an electrical signal. Acoustic waves enter through the first opening 124 to the front chamber 130 of the vibrating membrane 144. The sensing die 142 then detects or receives a signal indicative of a change in air pressure created by the acoustic waves between the front chamber 130 and the back chamber 148. The sound pressure causes the vibrating membrane 144 and output a signal indicative of the sound wave. This can generate a change in the capacitance, which is reflected by the variation of the voltage measured at the output.

The present disclosure may use a laser direct structuring (LDS) process to form the first and second conductive layers. The LDS technique includes moving a laser along the surface of a resin or the molding compound, which includes an additive that is activated by the laser. After activating the additive, a plating step forms a conductive material at the activated areas, forming the first and second conductive layers. Where the laser contacts the surface of the resin, it activates the additive forming a microscopically rough surface. The metal particles of this microscopically rough surface are what form the nuclei for the subsequent metallization.

FIG. 2 is a cross-sectional view of an alternative embodiment of a package 200. Many of the features of the substrate in FIG. 2 are similar to those in FIG. 1 and have not been described in detail, such as the substrate 112 is substantially the same in FIGS. 1 and 2. The package 200 includes the first die 118 embedded in the substrate 112, and the first opening 124 through the substrate 112.

An edge emitting laser die 208 is positioned on the first side of the substrate 112. The edge emitting laser die 208 is coupled to the first insulating layer 152 and the first conductive layer 102 with an adhesive 210. The first insulating layer 152 may completely cover the first conductive layer 102, such that the adhesive 210 is spaced from the first conductive layer by the first insulating layer. A contact 212 on the edge emitting laser die 208 is attached to a bonding wire 206. The bonding wire 206 extends from the contact 212 to the third conductive layer 104.

A prism or reflector 204 is positioned on the first side of the substrate 112 and on an opposite the opening 124 from the edge emitting laser die 208. The prism or reflector 204 is coupled to the first insulating layer 152 using an attach or adhesive 202. The prism or reflector 204 is partially aligned with and overlaps the first opening 124 through the substrate 112.

The prism is a passive element that includes a first end or surface 205 having a first dimension in a first direction. The prism includes a second end or surface 207 that has a second dimension in the first direction. The second dimension is greater than the first dimension. There is an angled surface 209 that extends between the first surface and the second surface. The angled surface 209 faces an edge 211 that is configured to emit a laser from the edge emitting die 208. The first surface is substantially parallel to the second surface. A third surface 213 that extends from the first surface to the second surface and is opposite to the angled surface 209 is transverse to the angled surface. The second surface 207 is spaced from the lid 138.

In the present embodiment, the edge emitting laser die 208 is a type of laser diode that emits light along the plane of the substrate 112 from the edge 211. The laser beam is generated from a cleaved edge of the edge emitting laser die 208 and transmits the light in a direction towards the angled surface of the prism or reflector 204. The prism or reflector 204 refracts the laser light outward through the first opening 124 and substrate 112. The laser beam from the edge emitting laser die 208 can be used for light detection and ranging (LiDAR), or for other remote sensing methods.

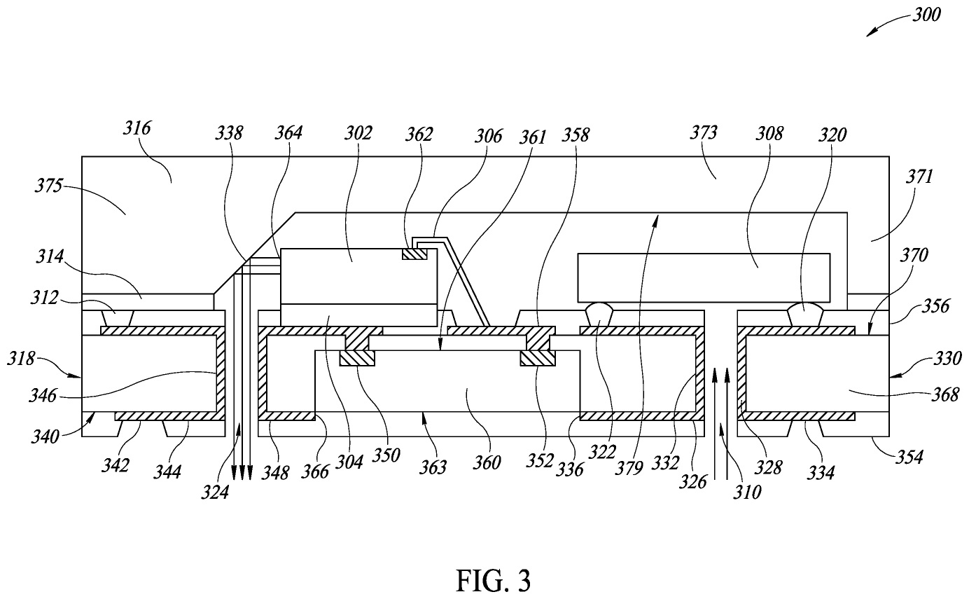

FIG. 3 is a cross-sectional view of an embodiment of a package 300 with a first die 360 embedded in a substrate 368. The first die 360 is positioned between a first opening 324 and a second opening 310, which are both fully through the substrate 368. The package 300 shows a second die, such as an edge emitting laser die 302 and a third die, such as a sensor die 308 that interacts with the second opening 310. The edge emitting laser die 302 and the sensor die 308 are positioned on a first surface 370 of the substrate 368. An integrated prism or reflector lid 316 is coupled to the first surface 370 and covers or otherwise surrounds the laser die and the sensor die.

The first die 360 in the substrate 368 is positioned between the first surface 370 and a second surface 340. The second opening 310 is adjacent to the first die 368 and transverse to the sensor die 308.

The first die 360 embedded in the substrate 368 has a first surface 361 and a second surface 363. The first opening 324 is adjacent to the first die 360 and is partially aligned with the edge emitting laser die 302. A first conductive layer 348 is on the first surface 370, on a sidewall 346 of the first opening 324. A second conductive layer 344 is also on the first surface 370, on a sidewall 365 in the first opening 324. The first opening 324 extends fully through the substrate 368 from a first insulating layer 356 to a second insulating layer 354. The first and second conductive layers 348, 344 may be electrically isolated, such as embodiments described in FIGS. 9 and 14 below.

The second surface 340 of the substrate is coplanar with the second surface 363 of the first die 360. The first die 360 has a first contact pad 350 and a second contact pad 352. The first contact pad 350 is coupled to the first conductive layer 348 that traces along the edge of the substrate 368 and lines the sidewall 346 of the first opening 324. The first conductive layer 348 extends from an edge 366 of the first die 360 to the sidewall 346 of the first opening 324. This is a first dimension along the second surface 340 of the substrate 368. The first conductive layer 348 extends from the opening 324 to a location between the first and second contact pads 350, 352 on the first die 360. The first conductive layer 348 is coupled to the first contact pad 350 through a via through the molding compound of the substrate 368. The first conductive layer 348 extends from the first opening past first contact pad 350, which is a second dimension, which is greater than the first dimension.

The second conductive layer 344 traces from the second surface 340 on the substrate 368 along the sidewall 346 of the first opening 324 to the first surface 370 of the substrate 368. An opening through the second insulating layer 354 exposes the second conductive layer 344 as a contact pad 342. The first insulating layer 356 includes an opening that provides access to the second conductive layer 344. The first and second insulating layers 356, 354 extend from a first edge 318 to the first opening 324, and is positioned or formed on the second conductive layer 344.

On the second side of the substrate 368, the first insulating layer 356 extends from the first opening 324 to the second opening 310. The first insulating layer 356 includes an opening that provides an access point to a third conductive layer 358 from the edge emitting laser die 302. The third conductive layer 358 is a trace formed on the substrate 368 and is coupled to the second contact pad 352 of the first die 360. The third conductive layer 358 is coupled by a wire 306 that extends from the third conductive layer 358 to a contact pad 362 on the edge emitting laser die 302. A fourth conductive layer 326 is on the first surface 370, on a sidewall 332 of the second opening 310 on the substrate 368. The fourth conductive layer 326 extends from a second edge 336 of the first die 360 to the sidewall 332 of the second opening 310. The fourth conductive layer 326 extends from the second opening 310 to a location on the first surface 370 between the second opening 310 and the third conductive layer 358. The fourth conductive layer 326 is coupled to the sensor die 308 by a first solder bump or electrical connection 322 through a via or opening through the first insulating layer 356.

On the third side of the substrate 368, the first and second insulating layers 356, 354 extend from the second opening 310 to a second edge 330. A fifth conductive layer 328 is on the first surface 370, on the sidewall 332 of the second opening 310 on the substrate 368. The fifth conductive layer 328 traces or extends from the second surface 340 on the substrate 368 along the sidewall 332 of the second opening 310 to the first surface 370 of the substrate 368. An opening through the second insulating layer 354 exposes the fifth conductive layer 328 as a contact pad 334. The fifth conductive layer 328 is coupled to the sensor die 308 by a second solder bump 320 through a via through the first insulating layer 356.

The sensor die 308 extends from the second side of the substrate 368 to the third side of the substrate 368. The sensor die 308 is opposite the edge emitting laser die 302, and transverse to the second opening 310. The first and second solder bumps 322, 320 allow interconnections not only on the peripheral of the sensor die 308, but over the entire surface. The sensor die 308 includes an active area of the chip that faces downward towards the second opening 310. The second opening 310 allows a laser through the substrate 368 to the sensor die 308.

An angled segment or surface 338 of an internal portion of the integrated prism or reflector lid 316 faces an edge 364 that is configured to emit a laser from the edge emitting laser die 302. The angled segment 338 extends from the lid attach 314 to an internal surface of the integrated prism or reflector lid 316 adjacent to the edge emitting laser die 302. The angled segment 338 is aligned with and overlaps the first opening 324 through the substrate 368.

The integrated prism or reflector lid 316 is attached to the first surface 370 by a lid adhesive 312 and a lid attach 314. On the first side of the substrate 368, the integrated prism or reflector lid 316 is coupled to the second conductive layer 344 through a via through the first insulating layer 356. The integrated prism or reflector lid 316 is aligned with both the first edge 318 and the second edge 330 of the substrate 368. The integrated prism or reflector lid 316 covers or otherwise surrounds the edge emitting laser die 302 and the sensor die 308.

The prism 316 may be a single molded or shaped component that includes a first extension 371 that is transverse to a top or second extension 373. A third extension 375 is transverse to the second extension 373 and is opposite to the first extension 371. The third and first extensions are not symmetrical in shape. The angled surface 338 is an integral part of the third extension that extends from the attach or adhesive 314 to an internal surface 379 of the second extension 373. Although the lid is an integrated prism in this embodiment, a different lid style may be incorporated with the three die of this package.

The package 300 includes the first die 360 embedded in the substrate 368 with the second die and the third die spaced from each other on the substrate. The third die is cooperatively positioned with respect to the second opening 310 and may directly overlap the second opening or be aligned to transmit or receive signals through the second opening.

The second die is also cooperatively positioned with respect to the first opening 324 such that signals may be transmitted or received through the opening.

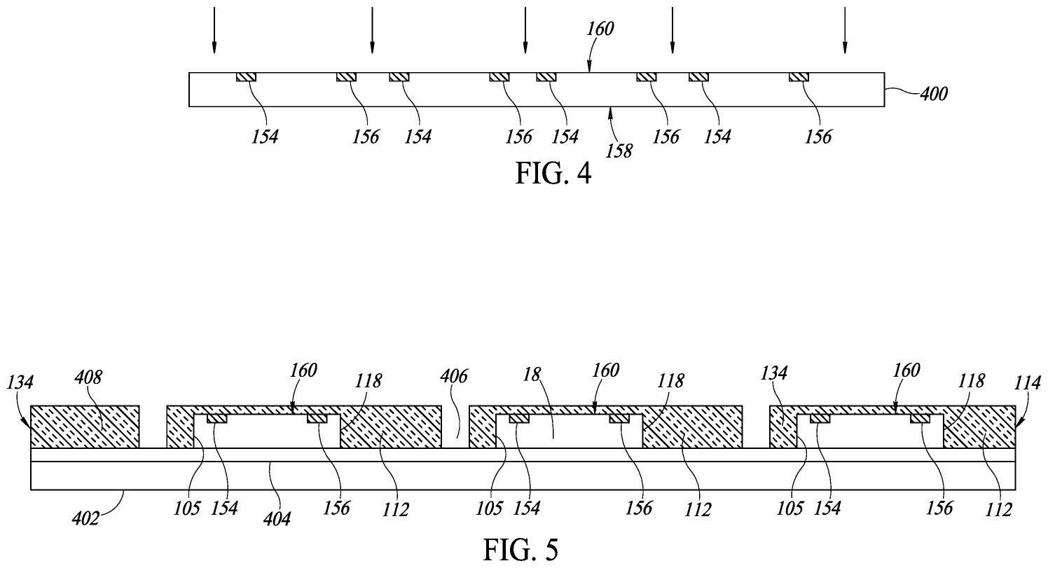

FIGS. 4-8 are steps of a method of forming the package 100 of FIG. 1. FIG. 4 is a cross-sectional view of a wafer 400 onto which a plurality of application specific integrated circuit (ASIC) or first die 118 are formed. Each first die includes a plurality of active and passive circuitry components to achieve the selected performance of the end use. Each of the plurality of the first die 118 has a first contact pad 154 and a second contact pad 156. The first die 118 has a first surface 158 and a second surface 160. The first and second contact pads 154, 156 are on the second surface 160 of the first die 118. The plurality of first die 118 are singulated or separated from each other as indicated by the arrows in FIG. 4. Each distinct die is then mounted on an intermediate carrier substrate 402, which may include an adhesive or support layer 404.

FIG. 5 is a cross-sectional view of the first die 118 affixed to the intermediate carrier substrate. The first die are reconstituted on the intermediate carrier substrate by encasing them in a laser reactive molding compound 408 to form the substrate 112. In some embodiments, the laser reactive molding compound may be replaced with a conventional molding compound that does not include the additives for formation of electrical traces or conductive tracks with a laser. The laser reactive molding compound includes a plurality of additives or activateable molecular structures that react to the application of a laser and form a thin layer of metal or a metal alloy in a very precise location. This laser direct structuring technique allows for non-traditional shapes for electrical connections as the laser can be moved and positioned in a more flexible manner than photolithography and masking techniques.

The laser reactive molding compound may be formed as a thick layer that covers every one of the first die and then a plurality of openings 406 may be formed. Alternatively, the laser reactive molding compound may be formed simultaneously with the openings 406. The openings may be formed by a mold and once cured, the mold is removed. The openings are between adjacent ones of the plurality of substrates 118. The surface 158 of the first die 118 is in direct contact with the carrier 402, such as the adhesive layer 404.

The laser reactive molding compound 112 surrounds the first die 118, extending from a first edge 134 to a second edge 114. The laser reactive molding compound 112 is in direct contact with the second surface 160 of the first die and with all sidewalls of the first die.

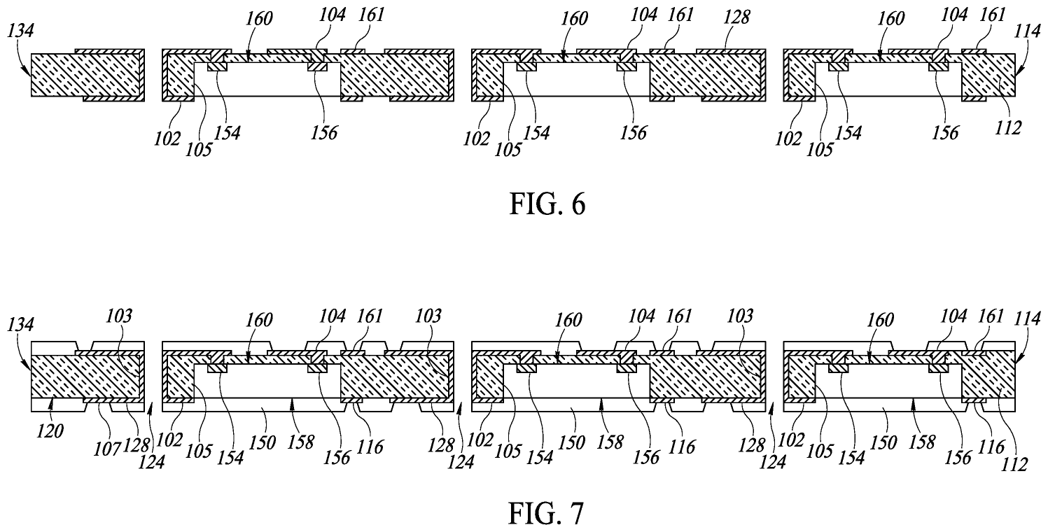

In FIG. 6, redistribution layers or conductive layers are formed on the laser reactive molding compound, first with application of the laser and then with a plating process for form the conductive layers to a selected thickness. The plating step effectively interacts with the activated additives from the application of the laser. As noted, in laser direct structuring, a laser is used to activate the surface of the laser reactive molding compound. The conductive layers are formed on the first and second surfaces of the laser reactive molding compound. The conductive layers trace or extend along the sidewall of the openings, and are electrically coupled to the contact pads on the first die 118. After the conductive layers are formed, plating is applied to the surface of the substrate using a plating process. Different combinations of electrical connections and coverage of the interior sidewalls of the openings are achievable with the flexibility of the laser direct structuring process, which can be used in small, precise configurations.

In FIG. 7, an insulating or dielectric layer is applied to the first and second surface of the laser reactive molding. The insulating layer is a solder mask or resist that covers portions of the conductive layers. The insulating layer is formed with openings on the first and second surface that enable access to the conductive layers as electrical contacts or lid support connections.

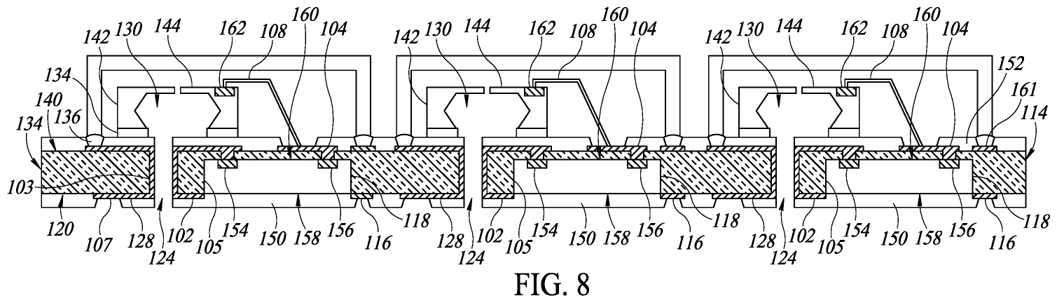

FIG. 8 is a cross-sectional view of the package with a sensing die 142 and a lid 138. The lid 138 is attached with conductive glue or solder paste 136 that may be reflowed to ground the lid 138. Typically, the lid is metal, but may be another material such as an integrated prism or reflector lid as in FIG. 3. Subsequent to the assembly of the package, aligning the sensing die with the opening 124 and creating the cavity with the lid, the plurality of packages are singulated or otherwise separated from each other to form the packages 100.

FIG. 9 is directed to an alternative embodiment of a package 900 having a plurality of distinct electrical connections 910a-c formed on a sidewall 901 of an opening 906 in a substrate 912. The plurality of electrical connections 910 may include a first connection 910a that is on a first surface 918 of the substrate 912 and extends to a second surface (not shown) with a portion extending along the sidewall 901 along a dimension of the opening. A second connection or conductive track 910b also includes a portion on the first surface, a portion that extends along the opening, and a portion that is on the second surface of the substrate. A plurality of dielectric layers or spacers 920 are positioned between adjacent ones of the plurality of electrical connections. Dimensions of each of the electrical connections can vary to accommodate different signals transmitted through the opening from one side of the substrate to the other. For example, the first electrical connection 910a has a larger surface area than the second connection 910b.

Dimensions of the dielectric spacers 920 may also vary such that adjacent dielectric spacers have different surface areas. In some embodiments, each spacer has an interior side having a first dimension and an exterior side 924 having a second dimension that is greater than the first dimension.

A first die 902 is positioned overlapping the opening 916 and a second die 904 is adjacent to the first die 902. Both are shown in dashed lines as they are not visible from the bottom view of the substrate. Ones of the plurality of electrical connections are coupled to contact pads on the first and second die. In addition, a plurality of contact pads 908 are exposed on the first surface of the substrate 912 and ones of the contact pads are coupled to ones of the plurality of electrical connections. The first die may be a micro-electromechanical sensor or other sensor where fluid is configured to pass or otherwise move through the opening and interact with the first die.

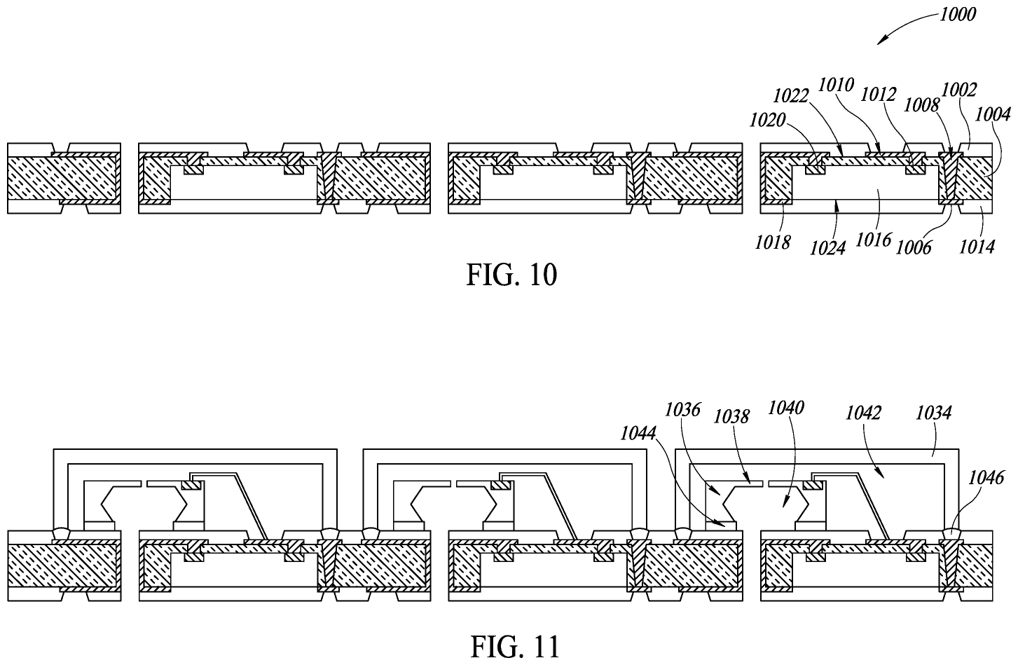

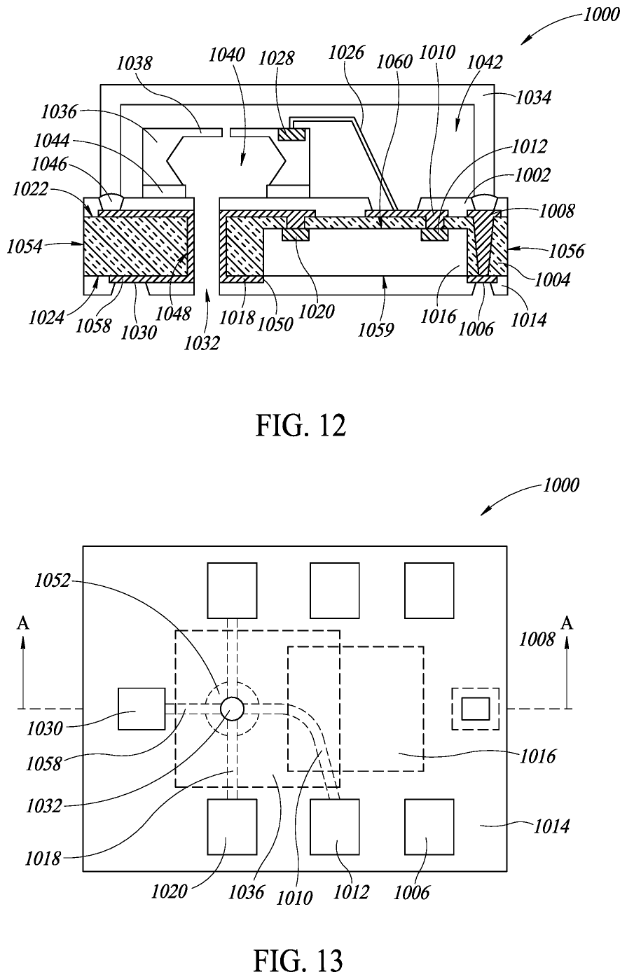

FIGS. 10-13 are an alternative package 1000 and steps of a method of forming the package 1000. FIG. 12 is a cross-sectional view of FIG. 13 through line A-A, with a first die 1016 embedded in a substrate 1004. The first die 1016 in the substrate 1004 is positioned between a first surface 1022 and a second surface 1024. A second die 1036, which may be a micro-electromechanical system or a MEMS sensor die is positioned on the substrate 1004 using a die attach or adhesive material 1044 between the MEMS sensor die 1036 and the first surface 1022. A lid 1034 is attached to the first surface 1022 and serves as a housing around the MEMS sensor die 1036, extending between a first edge 1054 of the substrate 1004 to a second edge 1056 of the substrate 1004. Ends of the lid being spaced inwardly from the first and second edge 1054, 1056 by a distance.

The first die 1016 embedded in the substrate 1004 has a first surface 1059 and a second surface 1060. A first opening 1032 is adjacent to the first die 1016 and is aligned with the second die 1036. A first conductive layer 1018 is on the first surface 1022, on a sidewall 1048 of the first opening 1032. A second conductive layer 1058 is also on the substrate 1004 and in the first opening 1032. The first opening 1032 extends from a first insulating layer 1002 to a second insulating layer 1014, through the substrate 1004 and aligned with the sensing die 1036. The first and second conductive layers may be electrically isolated, such as embodiments described in FIGS. 9 and 14 below.

The second surface 1024 of the substrate 1004 is coplanar with the first surface 1059 of the first die 1016. The second surface 1060 of the first die 1016 is coplanar with a first contact pad 1020 and a second contact pad 1012 in the first die 1016. The first contact pad 1020 is coupled to the first conductive layer 1018 that traces along the edge of the substrate 1004 and lines the sidewall 1048 of the first opening 1032. The first conductive layer 1018 extends from an edge 1050 of the first die 1016 to the sidewall 1048 of the first opening 1032. This is a first dimension along the second surface 1024 of the substrate 1004. The first conductive layer 1018 extends from the opening 1032 to a location between the first and second contact 1020, 1012 on the first die 1016. The first conductive layer 1018 is coupled to the first contact pad 1020 through a via through the molding compound of the substrate 1016. This is a second dimension on the first surface of the substrate. The second dimension is greater than the first dimension.

A second conductive layer 1058 traces from the second surface 1024 on the substrate 1004 along the sidewall of the first opening 1032 to the first surface 1022 of the substrate 1004. An opening through the second insulating layer 1014 exposes the second conductive layer 1058 as a contact pad 1030. The first insulating layer 1002 includes an opening that provides access to the second conductive layer 1058. The lid 1034 includes an attach 1046 that extends from the lid 1034, through the first insulating layer 1002 and is coupled to the second conductive layer 1058.

The lid 1034 is also coupled to a through via 1008 by the conductive adhesive or attach 1046. The through via 1008 extends through the substrate 1004 from the first surface 1022 to the second surface 1024. The through via 1008 is positioned between the first die 1016 and the second edge 1056. The through via 1008 may be formed by using laser direct structuring or plating. The through via 1008 is coupled to a contact pad 1006 on the second insulating layer 1014.

The first insulating layer 1002 extends from the first edge 1054 to the first opening 1032, and is positioned or formed on the second conductive layer 1058. The second insulating layer 1014 is extending from the first edge 1054 to the first opening 1032. On the second side of the substrate 1004, the first insulating layer 1002 extends from the first opening 1032 to a second edge 1056. The first insulating layer 1002 includes an opening that provides an access point to a third conductive layer 1010 from the sensing die 1036. The third conductive layer 1010 is a trace formed on the substrate 1004 and is coupled to the contact pad 1012. The third conductive layer 1010 is coupled by a wire 1026 that extends from the third conductive layer 1010 to a contact pad 1028 on the sensing die 1036.

On the second side of the substrate 1004, the second insulating layer 1014 extends from the opening 1032 to the second edge 1056, with an opening that provides access to the contact pad 1006. The second contact pad 1012 in the first die 1016 is coupled to a third conductive layer 1010 on the substrate 1004.

The first and second insulating layers 1002, 1014 may be solder resist or other known dielectric liner materials used in packaging techniques. In the present embodiment, the sensing die 1036 is positioned on the substrate 1004 and may contain a vibrating membrane 1038, which may be a MEMS microphone. The sensor die 1036 is coupled to the first insulating 1002 with the sensor attach 1044, such that a chamber 1040 is in fluid communication with the opening 1032 and the opening through the membrane or cantilever 1038. The lid 1034 also forms a chamber 1042 in which the MEMS sensor die 1036 is positioned.

FIG. 13 is a bottom plan view of the package 1000 with the first die 1016 embedded in the substrate 1004. In the present embodiment, the opening 1032 may be lined with electrical connections that are separated by a dielectric layer 1052. The second die 1036 is positioned overlapping the opening 1032 and the first die 1016. Both the first and second die 1016, 1032 are shown in dashed lines as they are not visible from the bottom view of the substrate. A plurality of electrical connections are coupled to contact pads, in which the electrical connections are shown in dashed lines because they are not visible from the bottom view of the substrate, i.e. the insulating layer 1014 covers the electrical connections 1018, 1010, and 1058.

The first electrical connection 1018 is coupled to the contact pad 1020 of the first die 1016. The second electrical connection 1058 is coupled to the contact pad 1030. The third electrical connection 1010 is coupled to second contact pad 1012 in the first die 1016. The fourth contact pad 1006 is exposed through a via in the second insulating layer 1014. In addition, the through via 1008 is shown exposed in the second insulating layer 1014 with a surrounding dashed line.

Each of the electrical connections are separated from each other by spacers like the dielectric layer 1052. The third electrical connection is curved from the opening 1032 to the second contact pad 1012. This is one example of irregular or curved patterns that can be achieved by using laser direct structuring (LDS) to form the electrical connections in a molding compound having LDS compatible additives.

The first die 1016 is closer to the contact pads, such as contact pad 1012 than the second die 1036. Said differently, the first die is between the second die and the contact pads on this bottom side of the package. A ratio of the size of the opening 1032 to an area of the second die 1036 is smaller in FIG. 13 than in FIG. 14. A variety of ratios are envisioned to address a variety of end uses.

FIG. 14 is a bottom plan view of an alternative embodiment of a package 1400. In the present embodiment, the package 1400 has an embedded first die 1406 in a substrate 1402 with an opening 1410 through the substrate 1402. The substrate may be a laser direct structuring compatible material that allows the electrical connections to be formed with a laser and to have a variety of non-traditional shapes as the flexibility of the laser's movement is more than traditional photolithographic and other etching techniques. The package 1400 includes a second die 1408 that overlaps the opening 1410 in the substrate 1402. The opening 1410 may have a dielectric layer 1412 that is formed around the opening 1410 to separate the electrical connections. From the opening 1410, a first electrical connection 1420 extends from the opening 1410 to a first contact 1422. A second electrical connection 1416 extends from the opening 1410 to a second contact 1414. A third electrical connection 1405 extends from the opening 1410 to a third contact 1404.

The various embodiments of the present disclosure allow for a smaller package that can be manufactured without purchasing a stand-alone substrate. Instead, the substrate is built with molding compound or a resin around the die in the substrate, such as an ASIC or an integrated circuit. When a laser direct structuring molding compound is used, some or all of the electrical connections on the substrate may be formed with a laser and a plating process. The electrical connections can traverse from one side of the substrate to the other side of the substrate, through the substrate or through an opening in the substrate. The openings through the molding compound or resin substrate may be formed by a mold that may be removed after a curing step. The lid is typically metal that is grounded by an electrical connection.

In some embodiments, the leads or electrical connections through the opening are partitioned or otherwise electrically isolated from each other by a dielectric spacer or material.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a substrate having a first surface and a second surface;
a first die in the substrate between the first surface and the second surface, the first die having a first contact;
a second die on the first surface of the substrate;
a first opening through the substrate from the first surface to the second surface;
a first conductive layer on the first surface of the substrate, on a sidewall of the first opening, and on the second surface of the substrate, the first conductive layer coupled to the first contact of the first die.

2. The device of claim 1, further comprising a second conductive layer on the first surface of the substrate, on the sidewall of the first opening, and on the second surface of the substrate.

3. The device of claim 2, further comprising a lid coupled to the substrate.

4. The device of claim 3 wherein the second conductive layer is coupled to the lid at the first surface of the substrate.

5. The device of claim 4, further comprising a dielectric layer on the first surface of the substrate, on the second surface of the substrate, and on the first and second conductive layers.

6. The device of claim 5, further comprising a second contact through the dielectric layer on the second surface of the substrate, the second contact being part of the second conductive layer.

7. The device of claim 1 wherein the first die includes a second contact, the first and second contact being closer to the first surface of the substrate than the second surface.

8. The device of claim 7 wherein the second die includes a third contact that is electrically coupled to the second contact of the first die.

9. The device of claim 1, further comprising a prism on the first surface of the substrate.

10. The device of claim 9 wherein the prism is spaced from the second die by the first opening.

11. The device of claim 10 wherein the prism is extends from a first edge of the substrate to a second edge of the substrate and covers the first die and the second die.

12. (canceled)

13. The device of claim 11, further comprising:
a third die on the first surface of the substrate; and
a second opening through the substrate, the third die aligned with the second opening.

14-24. (canceled)

25. A device, comprising:
a substrate having a first surface opposite to a second surface;
a first die in the substrate;
an opening through the substrate;
a first contact on the first die;
a first trace that is coupled to the first contact and extends from the first surface through the opening to the second surface of the substrate;
a second trace that extends from the first surface through the opening to the second surface of the substrate.

26. The device of claim 25 wherein the first trace is spaced apart from the second trace.

27. The device of claim 25, further comprising a second die on the substrate and configured to interact with the opening.

28. The device of claim 27 wherein the second die is coupled to the second trace.

29. A device, comprising:
a substrate having a first surface opposite to a second surface;
a first die in the substrate;
an opening through the substrate;
a first contact on the first die;
a second contact on the second surface of the substrate;
a first trace that is electrically coupled to the first contact and extends from the first surface through the opening to the second contact on the second surface of the substrate.

30. The device of claim 29, further comprising a second trace that extends from the first surface through the opening to the second surface of the substrate.

31. The device of claim 29, further comprising a second die on the first surface of the substrate in fluid communication with the opening.
